(19) United States
(12) Patent Application Publication
(10) Pub. No.: US 2006/0043570 A1
(43) Pub. Date: Mar. 2, 2006

(54) Substrate, semiconductor device, substrate fabricating method, and semiconductor device fabricating method

(76) Inventors: Shigetsugu Muramatsu, Nagano-shi (JP); Masahiro Kyozuka, Nagano-shi (JP); Motoyuki Komatsu, Nagano-shi (JP)

Correspondence Address: LADAS & PARRY LLP, 224 SOUTH MICHIGAN AVENUE, SUITE 1600, CHICAGO, IL, 60604, US

(21) Appl. No.: 11/193,243

(22) Filed: Jul. 29, 2005

(30) Foreign Application Priority Data
Aug. 25, 2004 (JP) 2004-245468

(51) Int. Cl. H01L 21/44; H01L 23/04

(52) U.S. Cl. 257/698; 257/700; 257/737; 438/613; 257/786; 438/612

(57) ABSTRACT

A semiconductor element having a first external connection terminal is connected to a substrate. The substrate includes a base material and a wiring portion, positioned at the first surface side of the base material. This configuration facilitates the realization of the connection between the first external connection terminal and the wiring portion. The wiring portion is positioned coplanar to the first surface of the base material. The substrate also includes a via portion that is integrally formed with the wiring portion and is arranged to penetrate the base material.

### BACKGROUND OF THE INVENTION

1. Field of the Invention

The present invention relates generally to a substrate, a semiconductor device, a substrate fabricating method, and a semiconductor device fabricating method, and particularly to a technique for mounting a semiconductor element to a substrate at a high density.

2. Description of the Related Art

FIGS. 1 and 2 illustrate the prior art, specifically, a semiconductor device 20. FIG. 1 is a cross-sectional view of the semiconductor device 20, and FIG. 2 is a cross-sectional view of a substrate 10 of the semiconductor device 20, shown in FIG. 1.

The semiconductor device 20 is comprised of a substrate 10 and a semiconductor element 23 mounted on solder bumps 24. It should be noted that connection pads 15 of the substrate 10 are connected to the solder bumps 24 of the semiconductor element 23 (through flip chip connection), and underfill resin 26 is distributed between the semiconductor element 23 and the substrate 10.

The substrate 10 includes a resin base material 11, through holes 12, vias 13, wirings 14 and 17, connection pads 15 and 18, solder resists 16 and 19, and solder balls 21. It should also be noted that the substrate 10 is configured to realize electrical connection between the semiconductor element 23 and a motherboard (not shown).

Vias 13 are arranged at through holes 12 which penetrate resin base material 11, and connect to wirings 14. Wirings 14 are arranged on a surface 11A of the resin base material 11, and are connected to connection pads 15. For example, connection pads 15 are arranged on surface 11A and are configured to connect the semiconductor device 23 to solder bumps 24. Wirings 14 and connection pads 15 can be formed by laminating Cu foil on the surface 11A of the base material 11, patterning a resist film which corresponds to the shape of wirings 14 and connection pads 15, and conducting an etching process using the patterned resist film as a mask (e.g., see Japanese Laid-Open Patent Publication No. 2000-165049).

Solder resist 16 covers the surface 11A of the resin base material 11 and the wirings 14, exposing the connection pads 15. Wirings 17 are arranged on a surface 11B of the resin base material 11, and are connected to the vias 13. For example, connection pads 18 are arranged on the surface 11B of the resin base material and are connected to wirings 17. Connection pads 18 are configured to be connected to solder balls 21. Wirings 17 and connection pads 18 are formed by laminating surface 11B of base material 11 with Cu foil, patterning a resist film corresponding to the shape of wirings 17 and connection pads 18, and conducting an etching process using the patterned resist film as a mask (e.g., see Japanese Laid-Open Patent Publication No. 2000-165049).

Solder resist 19 covers surface 11B of the resin base layer 11 and wirings 17, exposing connection pads 18. Solder balls 21 are arranged at the connection pads 18, and are connected to a motherboard (not shown). Connection pads 15, connected to resin base material 10 (described above), are connected to solder bumps 24 of the semiconductor device 23.

Underfill resin 26, which is distributed between the solder resist 16 and the semiconductor element 23, strengthens the connection between semiconductor element 23 and resin base material 11. As a result, underfill resin 26 improves connection reliability between resin base material 10 and semiconductor element 23.

FIG. 3 is an enlarged view of the connection between the semiconductor element 23 and the resin base material 11. As shown in FIG. 3, gap D1 is formed between semiconductor element 23 and a portion of the solder resist 16 covering the resin base material 11, and gap D2 is formed between the semiconductor element 23 and a portion of the solder resist 16 covering the wirings 14. The solder bump 24 is arranged to have a height H1. As shown in FIG. 3, wirings 14 are arranged in Region A, while Region B contains neither the wirings 14 nor the connection pads 15.

According to the prior art, the side of the resin base material 11 on which the semiconductor element 23 is mounted includes Region A and Region B; connection pads 15 and wirings 14 are arranged to protrude from the surface 11A of the resin base material 11. As a result, the upper surface 16A of the solder resist 16 formed on the resin base material 11 may be uneven or ridged. Gap D2 in Region A is narrower than gap D1 in Region B. Thus, after the gap between the semiconductor element 23 and the resin base material 11 has been filled with underfill resin 26, the resin may not distribute evenly resulting in insufficient resin thickness in Region B.

Furthermore, this problem has only been exacerbated by the increase in the speed and functions of the semiconductor element, the increase in the number of terminals due to higher integration of the semiconductor element, and the continual decrease in the mounting pitch of the semiconductor element in recent years; with these development in the art, both the height H1 of the solder bumps 24 and the width of gap D2 continue to decrease. Accordingly, this makes even distribution of underfill resin in gap D2 increasingly difficult.

Additionally, as semiconductor elements become increasingly smaller, the thickness of the resin base material 11 may be reduced even further, leading to a further decrease in the strength of the resin base material. Consequently, the resin base material 11 may become deformed, resulting in an inadequate connection between semiconductor element 23 and resin base material 11.

### SUMMARY OF THE INVENTION

The present invention has been conceived in response to the aforementioned defects in the prior art, with the goal of providing an effective technique for ensuring sufficient resin thickness and even distribution of underfill resin, thereby facilitating a connection reliability between the semiconductor element and the substrate.

One embodiment of the invention is comprised of substrate connected to a semiconductor element with a first external connection terminal. The substrate is comprised of:

a base material;

a wiring portion positioned at the first surface side of the base material and configured to realize the connection with the first external connection terminal, wherein said wiring portion is arranged to be coplanar with the first surface of the base material; and

a via portion adjacent to the wiring portion, arranged to penetrate the base material.

According to an aspect of the embodiment described above, the wiring portion is arranged to be coplanar with the surface of the base material at which the wiring portion is positioned, and thereby, forming a sufficiently wide gap between the semiconductor element and the substrate upon connecting the semiconductor element to the substrate.

In a preferred embodiment, the substrate of the present invention further comprises:

an insulating layer that is arranged on the first surface side of the base material; wherein

the wiring portion includes a connection pad to which the first external connection terminal is connected and wiring for realizing connection between the connection pad and the via portion; and

the insulating layer is arranged to cover the via portion and the wiring, and expose the connection pad.

According to an aspect of the embodiment described above, the wiring portion is coplanar with the surface of the base material, thereby, creating a smooth insulating layer surface, forming an even and sufficient wide gap between the semiconductor element and the insulating layer arranged on the substrate.

In another preferred embodiment, the substrate of the present invention further comprises:

a second external connection terminal that is configured to realize connection with another substrate, wherein the second external connection terminal is connected to the via portion at a second surface side of the base material on the opposite side of the first surface.

In another preferred embodiment of the present invention, the second external connection terminal is connected to the via portion at the side of the base material opposite the wiring portion, thereby, reducing the thickness of the substrate in comparison to the prior art, and facilitating miniaturization of the substrate.

According to another embodiment of the present invention, the substrate is connected to a semiconductor element with a first external connection terminal, wherein said substrate is comprised of:

a base material;

a second external connection terminal configured to realize a connection with another substrate;

a wiring portion positioned at the first surface side of the base material, configured to realize connection with the second external connection terminal, wherein said wiring portion is coplanar with the first surface of the base material;

a via portion which is integrally connected with the wiring portion and penetrates the base material;

wherein the first external connection terminal is connected to the via portion at the second surface side of the base material, opposite the first surface.

According to an aspect of the embodiment described above, the first external connection terminal of the semiconductor element is connected to the via portion, which is coplanar with the surface of the base material, thereby, forming an even and sufficiently wide gap between the substrate and the semiconductor element connected to the substrate. Also, according to another an aspect of the embodiment described above, the wiring portion is coplanar with the surface of the base material, thereby, reducing the thickness of the substrate in comparison to the prior art and facilitating miniaturization of the substrate.

In a preferred embodiment, the substrate of the present invention further is comprised of:

an insulating layer on the first surface side of the base material; wherein

the wiring portion is comprised of a connection pad connected to the second external connection terminal, and a wiring for realizing the connection between the connection pad and the via portion; and

the insulating layer is arranged to cover the via portion and the wiring, and expose the connection pad.

According to an aspect of the present invention, the wiring portion is coplanar with the surface of the base material, and thereby, allowing the surface of the insulating layer to be free of ruts or grooves.

In another embodiment of the present invention, the semiconductor device is comprised of:

a semiconductor element having a first external connection terminal;

a substrate according to the present invention; and

an underfill material in the gap between the semiconductor element and the substrate.

In another aspect of the embodiment described above, the underfill material may be evenly distributed with a sufficient thickness in the gap between the semiconductor element and the substrate, ensuring connection reliability between the substrate and the semiconductor element.

Another embodiment of the present invention provides a method for producing a substrate connected to a semiconductor element having a first external connection terminal, wherein the substrate comprises a base material, a wiring portion connected to the first external connection terminal, and a second external connection terminal for realizing a connection with another substrate, the method is comprised of:

an opening formation step for forming an opening at the base material with a trench portion and a through hole;

a metal film formation step for forming a metal film at an inner wall of said opening; and

a plating film formation step for forming a plating film at said opening through electroplating using the metal film as a current supply layer and inducing deposition growth of the plating film, forming a via portion at the through hole, where the via portion is connected to the second external connection terminal., and forming a wiring portion at the trench portion, which the first external connection terminal is connected.

According to an aspect of the embodiment described above, by forming the opening corresponding to a combined structure of the trench portion and the through hole, forming the metal film, and forming the plating film at the opening through electroplating, the wiring portion connected to the first external connection terminal and the via portion may be positioned in a coplanar fashion with the surface of the base material.

In another preferred embodiment, the method according to the present invention further comprises:

a plating film polishing step performed when the plating film produced in the plating film formation step protrudes from a surface of the base material, wherein said plating film polishing step involves polishing the protruding plating film and positioning the plating film coplanar to the surface of the base material.

According to an aspect of the embodiment described above, when the plating film protrudes from the surface of the base material, the plating film is polished so as to be coplanar with the surface of the base material, and thereby, allowing the wiring portion and the via portion to be arranged in a coplanar fashion with the surface of the base material.

In another preferred embodiment, the method of the present invention further comprises:

an insulating layer formation step for forming an insulating layer on the base material; wherein

the wiring portion includes a connection pad to which the first external connection terminal is connected and wiring for realizing connection between the connection pad and the via portion; and

the insulating layer is arranged to cover the via portion and the wiring, and expose the connection pad.

According to an aspect of the embodiment described above, the wiring is coplanar with the surface of the base material, thereby, allowing the surface of the insulating layer covering the wiring and the via portion to be free of ruts or grooves and forming an even and sufficiently wide gap between the substrate and the semiconductor element connected to the substrate.

In another embodiment of the present invention, a method of fabricating a semiconductor device is provided that includes a substrate having a base material and a wiring portion, a semiconductor element having a first external connection terminal connected to the wiring portion, and an underfill material at a gap formed between the substrate and the semiconductor element connected to said substrate, the method comprising:

a base material providing step for providing the base material on a support member that is configured to support the base material;

a substrate fabricating step for fabricating the substrate according to the method of the present invention;

a semiconductor element connection step for connecting the first external connection terminal to the wiring portion;

an underfill material providing step for providing the underfill material at the gap formed between the semiconductor element and the substrate; and

a support member removal step for removing the support member.

According to an aspect of the embodiment described above, by fabricating the substrate according to the method of the present invention, the substrate may form properly even when the thickness of the base material is relatively thin. Also, by supporting the base material with the support member upon connecting the substrate to the semiconductor element, a secure connection between the substrate and the semiconductor element may be realized even when the thickness of the base material is relatively thin.

Another embodiment of the present invention provides a method of fabricating a substrate, wherein said substrate connected to a semiconductor element having a first external connection terminal, wherein said substrate includes a base material, a second external connection terminal for realizing connection with another substrate, and a wiring portion to which the second external connection terminal is connected, the method comprises:

an opening formation step for forming an opening at the base material that includes a trench portion and a through hole;

a metal film formation step for forming a metal film at an inner wall of the opening; and

a plating film formation step for forming a plating film at the opening through electroplating using the metal film as a current supply layer and inducing deposition growth of the plating film, forming at the through hole a via portion to which the first external connection terminal is connected, and forming a wiring portion at the trench portion, where the second external connection terminal is connected.

In another aspect of the embodiment described above, by arranging the via portion connected to the semiconductor element to be coplanar with a surface of the base material, and forming an even and sufficiently wide gap between the substrate and the semiconductor element connected to the substrate.

Another preferred embodiment provides a method further comprised of:

a plating film polishing step that is performed when the plating film formed in the plating film formation step protrudes from a surface of the base material, wherein said plating film polishing step involves polishing the protruding plating film and arranging the plating film coplanar to the surface of the base material.

In another aspect of the embodiment described above, when the plating film protrudes from the surface of the base material, the plating film is polished so as to be coplanar with the surface of the base material, thereby, positioning the wiring portion and the via portion coplanar to the surface of the base material at which the wiring portion is provided. Accordingly, the thickness of the substrate may be reduced compared to the substrate of the prior art having a wiring portion that protrudes from the surface of the base material, and miniaturization of the substrate may be realized.

Another preferred embodiment provides a method further comprising:

an insulating layer formation step for forming an insulating layer on the base material; wherein

the wiring portion includes a connection pad to which the second external connection terminal is connected and wiring for realizing connection between the connection pad and the via portion; and

the insulating layer is arranged to cover the via portion and the wiring, and expose the connection pad.

According to an aspect of the embodiment described above, the wiring portion connected to the second external connection terminal is coplanar with the surface of the base material, and thereby, allowing the surface of the insulating layer covering the via portion and the wiring to be free of bumps.

### BRIEF DESCRIPTION OF THE DRAWINGS

FIG. 1 is a cross-sectional view of a semiconductor device according to the prior art;

FIG. 2 is a cross-sectional view of a substrate of the semiconductor device shown in FIG. 1;

FIG. 3 is an enlarged cross-sectional view showing the connection between a semiconductor element and the substrate of the semiconductor device shown in FIG. 1;

FIG. 4 is a cross-sectional view of a semiconductor device according to a first embodiment of the present invention;

FIG. 5 is a cross-sectional view of a substrate of the semiconductor device according to the first embodiment;

FIG. 6 is a plan view of the substrate shown in FIG. 5;

FIG. 7 is another plan view of the substrate shown in FIG. 5;

FIG. 8 is a diagram illustrating a first process step for fabricating the semiconductor device according to the first embodiment;

FIG. 9 is a diagram illustrating a second process step for fabricating the semiconductor device according to the first embodiment;

FIG. 10 is a diagram illustrating a third process step for fabricating the semiconductor device according to the first embodiment;

FIG. 11 is a diagram illustrating a fourth process step for fabricating the semiconductor device according to the first embodiment;

FIG. 12 is a diagram illustrating a fifth process step for fabricating the semiconductor device according to the first embodiment;

FIG. 13 is a diagram illustrating a sixth process step for fabricating the semiconductor device according to the first embodiment;

FIG. 14 is a diagram illustrating a seventh process step for fabricating the semiconductor device according to the first embodiment;

FIG. 15 is a diagram illustrating an eighth process step for fabricating the semiconductor device according to the first embodiment;

FIG. 16 is a diagram illustrating a ninth process step for fabricating the semiconductor device according to the first embodiment;

FIG. 17 is a diagram illustrating a tenth process step for fabricating the semiconductor device according to the first embodiment;

FIG. 18 is a diagram illustrating an eleventh process step for fabricating the semiconductor device according to the first embodiment;

FIG. 19 is a diagram illustrating a twelfth process step for fabricating the semiconductor device according to the first embodiment;

FIG. 20 is a diagram illustrating a thirteenth process step for fabricating the semiconductor device according to the first embodiment;

FIG. 21 is a diagram illustrating a process step of forming a Cu plating film on the structure shown in FIG. 11 through deposition growth;

FIG. 22 is a cross-sectional view of a semiconductor device according to a second embodiment of the present invention;

FIG. 23 is a cross-sectional view of a substrate according to the second embodiment;

FIG. 24 is a plan view of the substrate shown in FIG. 23;

FIG. 25 is another plan view of the substrate shown in FIG. 23;

FIG. 26 is a diagram illustrating a first process step for fabricating the substrate according to the second embodiment;

FIG. 27 is a diagram illustrating a second process step for fabricating the substrate according to the second embodiment;

FIG. 28 is a diagram illustrating a third process step for fabricating the substrate according to the second embodiment;

FIG. 29 is a diagram illustrating a fourth process step for fabricating the substrate according to the second embodiment;

FIG. 30 is a diagram illustrating a fifth process step for fabricating the substrate according to the second embodiment;

FIG. 31 is a diagram illustrating a sixth process step for fabricating the substrate according to the second embodiment;

FIG. 32 is a diagram illustrating a seventh process step for fabricating the substrate according to the second embodiment;

FIG. 33 is a diagram illustrating an eighth process step for fabricating the substrate according to the second embodiment;

FIG. 34 is a diagram illustrating a ninth process step for fabricating the substrate according to the second embodiment;

FIG. 35 is a diagram illustrating a tenth process step for fabricating the substrate according to the second embodiment;

FIG. 36 is a diagram illustrating an eleventh process step for fabricating the substrate according to the second embodiment;

FIG. 37 is a cross-sectional view of the semiconductor device that is formed by connecting a semiconductor element to the substrate shown in FIG. 36; and

FIG. 38 is a diagram illustrating a process step of forming a Cu plating film through deposition growth on the structure shown in FIG. 29.

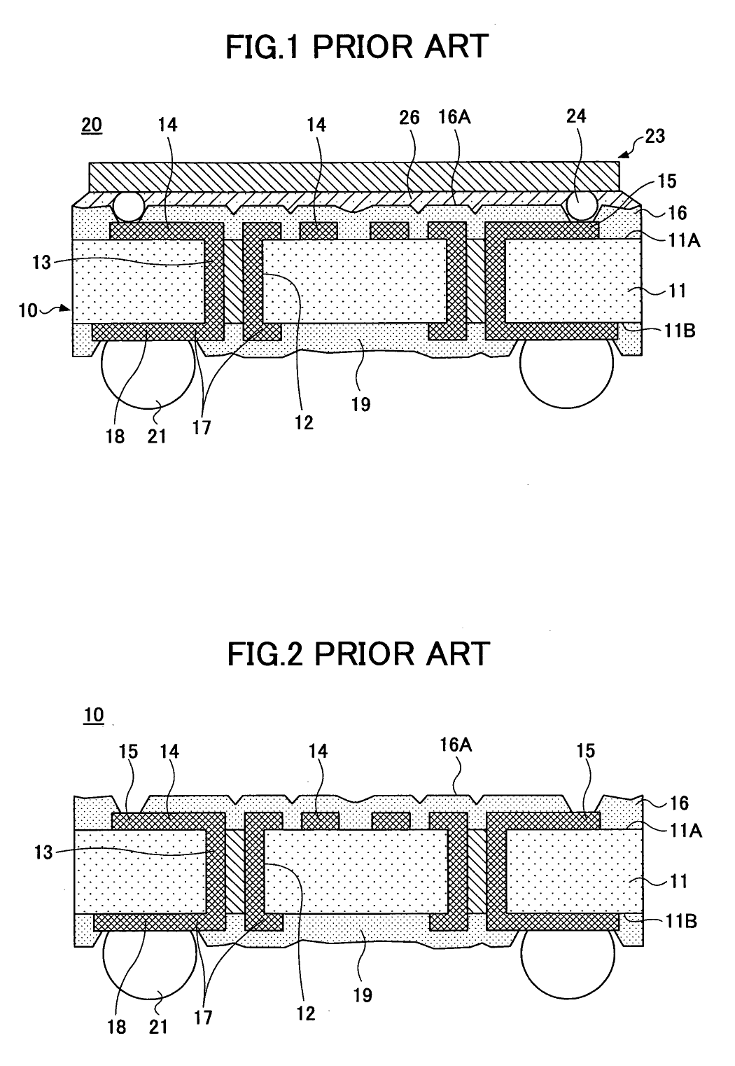

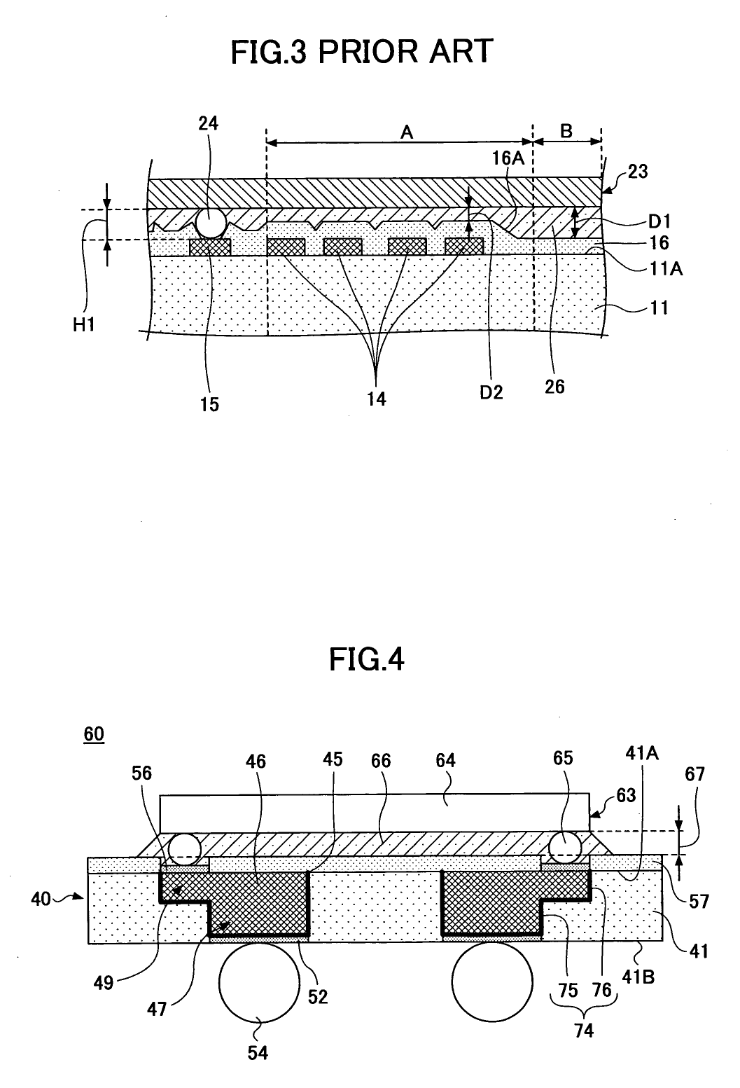

### DETAILED DESCRIPTION OF THE PREFERRED EMBODIMENTS

Preferred embodiments of the present invention will hereinafter be described in detail with reference to the accompanying drawings.

### First Embodiment

First, FIG. 4 illustrates the first embodiment of the present invention, specifically, semiconductor device 60. FIG. 4 is a cross-sectional view of the semiconductor device 60 according to the first embodiment of the invention. The semiconductor device 60 includes a substrate 40 and a semiconductor element 63. The semiconductor device 60 is arranged such that the semiconductor element 63 is flip-chip connected to the substrate 40, and underfill resin 66 is distributed within gap 67 between a semiconductor element main body 64 and substrate 40. Underfill resin 66 is configured to protect solder bumps 65 that are connected to the substrate 40 so as to improve the connection reliability between the substrate 40 and the semiconductor element 63. The semiconductor element 63 includes the semiconductor element main body 64 and the bumps 65, which correspond to first external connection terminals. The solder bumps 65 are connected to connection pads 49 of the substrate 40 via diffusion barrier film 56.

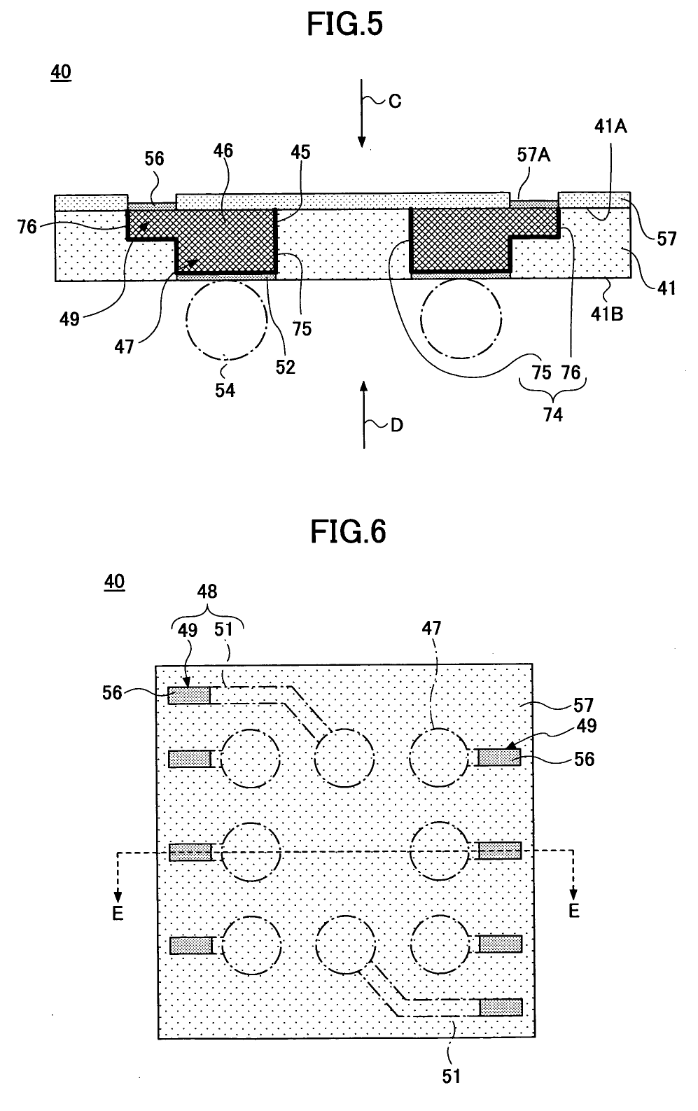

In the following, the substrate according to the present embodiment is described with reference to FIGS. 5 through 7.

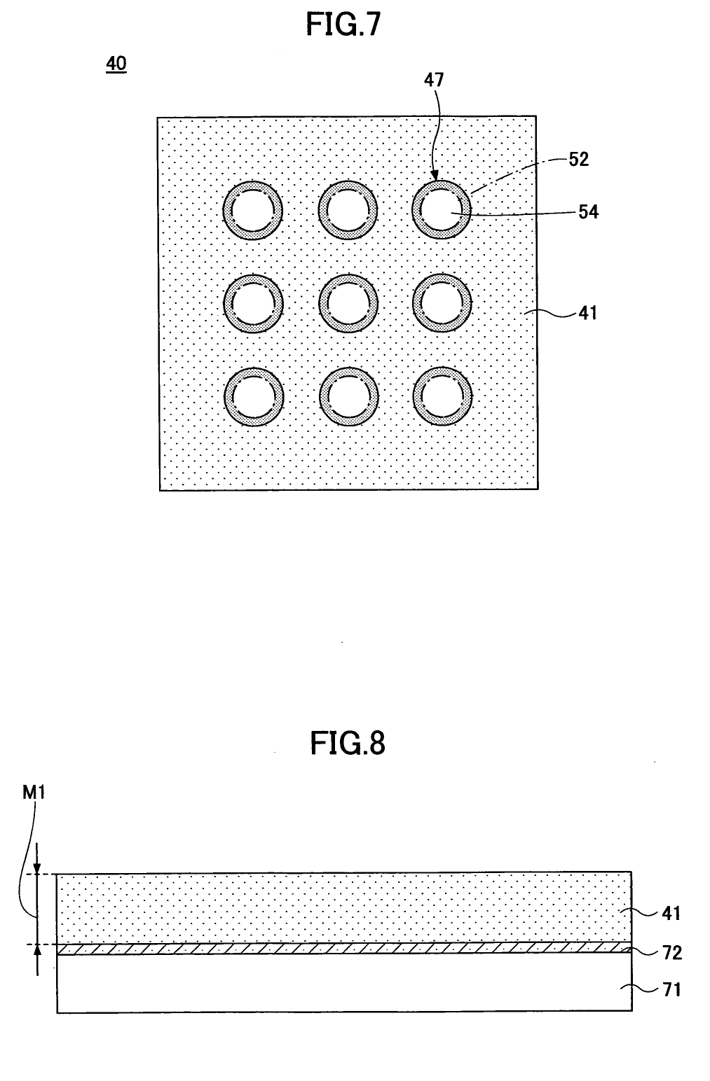

FIG. 5 is a cross-sectional view of the substrate 40 according to the first embodiment cut across line E-E of FIG. 6; FIG. 6 is a plan view of the substrate 40 viewed from side C of FIG. 5; and FIG. 7 is a plan view of the substrate 40 viewed from side D of FIG. 5.

Substrate 40 includes base material 41, via portions 47, wiring portions 48, diffusion barrier films 52 and 56, and a solder resist 57. Openings 74 are formed at base material 41 for accommodating the via portions 47 and the wiring portions 48. The openings 74 include through holes 75 for accommodating the via portions 47, and trench portions 76 for accommodating the wiring portions 48. For example, base material 41 may correspond to a resin base material. It should be noted that in the following description of the present embodiment, it is assumed that a resin base material is used as the base material 41.

The via portions 47 provided at the through holes 75 are arranged to penetrate through the base material 41. The via portions 47 form integral structures with their corresponding wiring portions 48 provided at the trench portions 76. The via portions 47 are connected to solder balls 54, and the connection pads 49 of the wiring portions 48 are connected to the solder bumps 65 of the semiconductor element 63. The via portions 47 and the wiring portions 48 are formed by a metal film 45 and a Cu plating film 46. The metal film 45 corresponds to a current supply layer used for forming the Cu plating film 46 through electroplating. For example, a Ni film or a Cu film that is formed through electroless plating may be used as the metal film 45.

It should be noted that the diffusion barrier film 52 is arranged at the ends of the via portions 47 on the surface 41B side of the base material 41. The diffusion barrier film 52 is configured to improve the wettability of solder and prevent diffusion of Cu contained in the via portions 47 into the solder balls 54. For example, aNi/Au layer may be used as the diffusion barrier film 52. The solder balls 54 corresponding to second external connection terminals are mounted on the diffusion barrier film 52 after the semiconductor element 63 is mounted on the substrate 40 and the underfill resin 66 is poured into gap 67 between the semiconductor element main body 64 and the substrate 40. The solder balls 54 are configured to realize electrical connection between the substrate 40 and another substrate, such as a motherboard.

Wiring portions 48 are arranged on the surface 41A side of the base material 41, and include the connection pads 49 and the wirings 51 (see FIG. 6). Connection pads 49 are connected to solder bumps 65 of semiconductor element 63, and wirings 51 are configured to realize electrical connection between connection pads 49 and via portions 47. Connection pads 49 and wirings 51 making up wiring portions 48 are arranged to be coplanar with the surface 41A of the base material 41. The solder resist 57, which corresponds to an insulating film, is arranged to cover the via portions 47 and wirings 51 formed at the surface 41A side of the base material 41, and expose connection pads 49.

By positioning wiring portions 48 coplanar with surface 41A of the base material 41 as described above, gap 67 between the semiconductor main body 64 and solder resist 57 provided at substrate 40 may be sufficiently wide and even when solder bumps 65 are connected to connection pads 49. Accordingly, underfill resin 66 may be distributed evenly within gap 67, preserving connection reliability between the semiconductor element 63 and the substrate 40.

Connection pads 49 exposed by the solder resist 57 are connected to the diffusion barrier film 56. The diffusion barrier film 56 is configured to improve the wettability of solder and prevent diffusion of Cu contained in the connection pads 49 into the solder bumps 65. For example, a Ni/Au layer may be used as the diffusion barrier film 56.

A method of fabricating the semiconductor device 60 according to the first embodiment is described with reference to FIGS. 8 through 21.

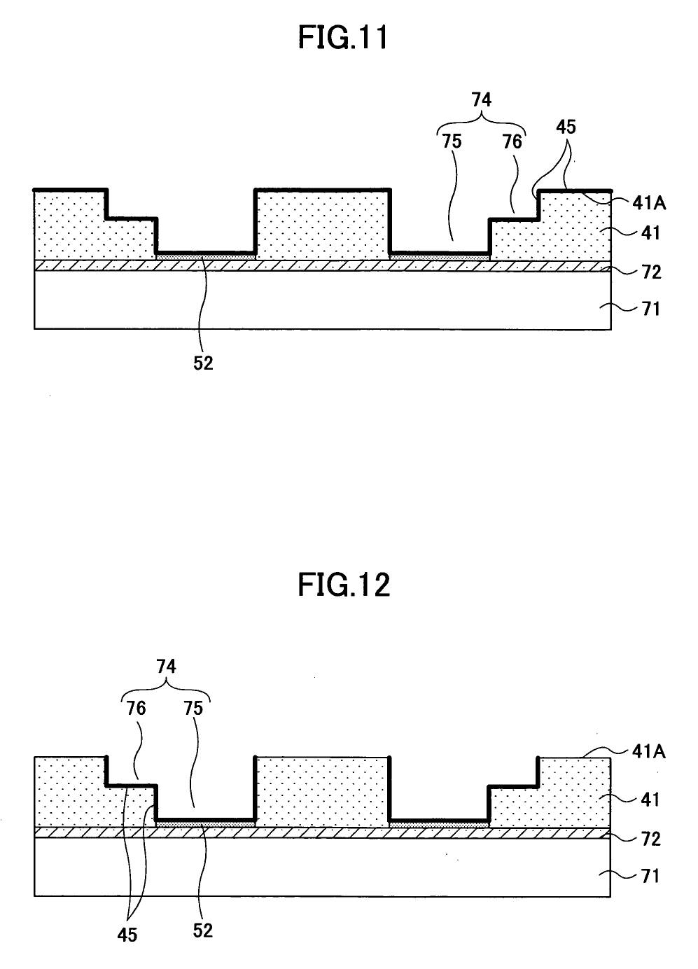

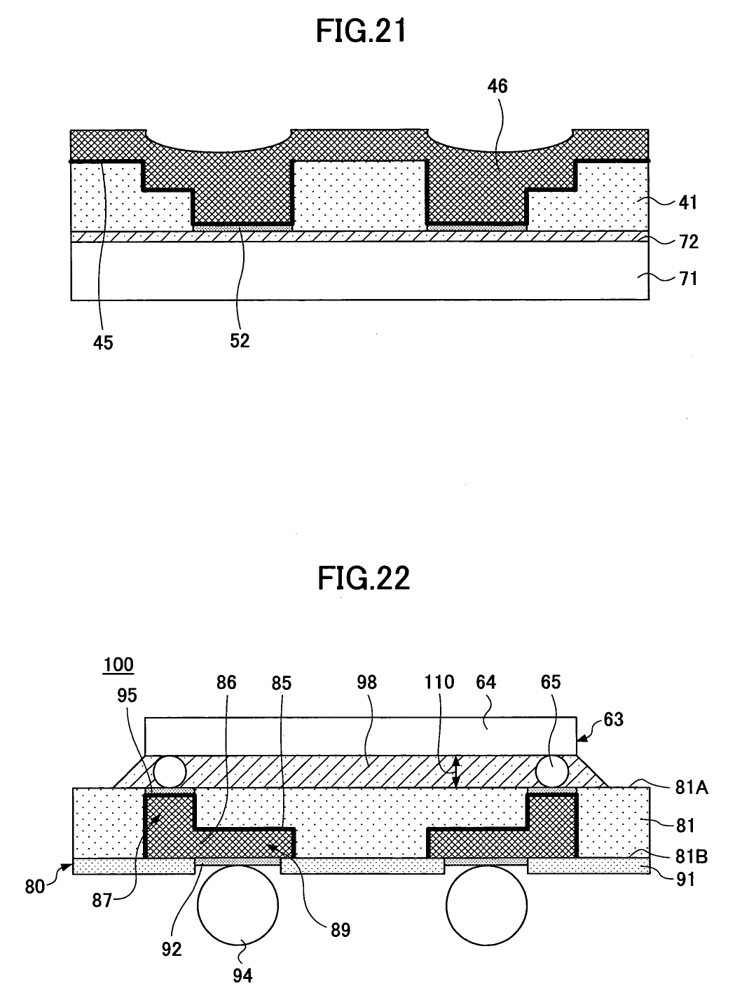

FIGS. 8 through 20 are diagrams illustrating process steps for fabricating the semiconductor device 60 according to the first embodiment. FIG. 21 is a diagram illustrating a process step of forming the Cu plating film 46 on the structure shown in FIG. 11 through deposition growth. In FIGS. 8 through 21, components that are identical to those of the semiconductor device 60 shown in FIG. 4 are assigned the same reference numerals.

First, as shown in FIG. 8, a metal layer 72 is positioned on a support member 71, and the base material 41 is positioned on the support member 71 via the metal layer 72 (base material mounting step). Support member 71 is positioned in order to prevent deformation such as bending and warping of the base material 41 that may occur when the thickness M1 of the base material 41 is relatively thin. For example, a resin sheet made of resin material such epoxy or polyimide, or a metal sheet made of metal such as aluminum or copper may be used as the support member 71. When using a metal sheet as support member 71, metal layer 72 does not have to be provided, and, accordingly, one may omit the step of preparing metal layer 72.

By mounting the base material 41 on the support member 71, substrate 40 forms properly even when the thickness M1 of the base material 41 is relatively thin. Metal layer 72 corresponds to a current supply layer that is used upon forming the diffusion barrier film 52 through electroplating. For example, metal layer 72 is prepared using a electroless plating process or a sputtering process. Also, materials such as Cu, Ni, or Al may be used in the preparation of metal layer 72. According to an embodiment, the base material 41 may be prepared by applying resin on the support member 71 with the metal layer 72 provided thereon.

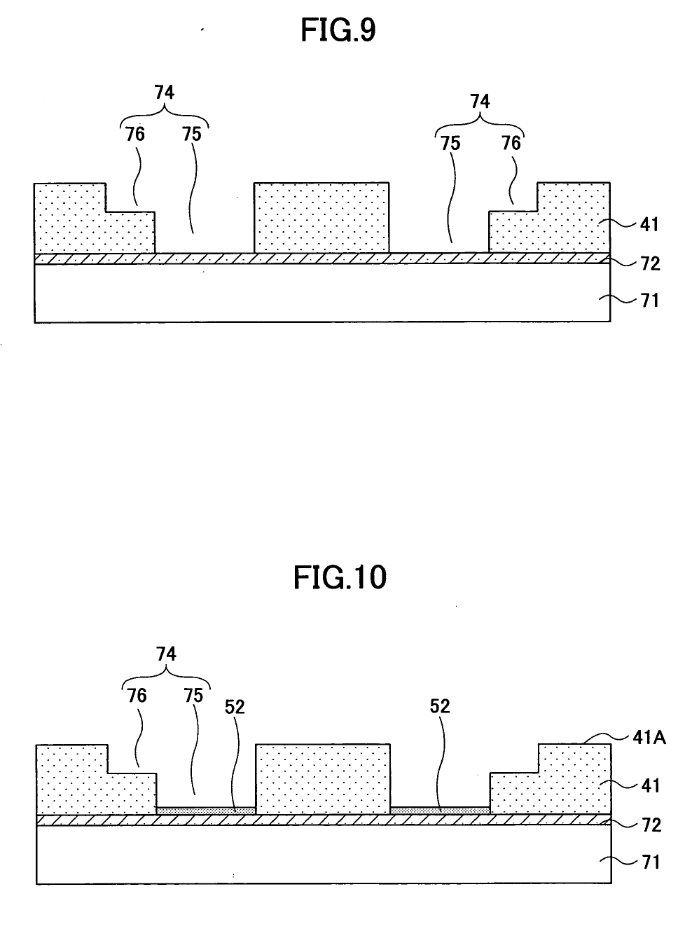

Next, as shown in FIG. 9, openings 74 corresponding to combined structures of the trench portions 76 and the through holes 75 are formed at the base material 41 (opening formation step). Through holes 75 are arranged to expose the metal layer 72. Openings 74 may be formed by a drilling process, for example, using a drill, a laser process, or an imprint process using a microscopic tool. When using an imprint process, resin (corresponding to the base material 41 of FIG. 9) may be applied to the support member 71 with the metal layer 72 formed thereon, or a resin film (corresponding to the base material 41 of FIG. 9) may be laminated on the support member 71. Then, the resin (or resin film) is semi-hardened, and a microscopic tool having convex portions for forming the openings 74 is pressed to the semi-hardened resin (or resin film) so that the shape of the convex portions of the microscopic tool are transferred to the resin (or resin film). Then, the resin (or resin film) is hardened through a thermal process to form openings 74 on the base material 41.

Next, as shown in FIG. 10, metal layer 72 is used as a current supply layer to form the diffusion barrier film 52 at the bottom portions of the through holes 75 through electroplating. Alternatively, the solder film (formed through solder plating) suitable for realizing connection with the solder balls 54 may act as a substitute for diffusion barrier film 52. Next, as shown in FIG. 11, metal film 45 is formed on the structure shown in FIG. 10. Metal film 45 corresponds to a current supply layer for inducing deposition growth of the Cu plating film 46 at openings 74. Metal film 45 may be prepared using a electroless plating or sputtering process, for example. Furthermore, copper or nickel may be also used as the material of the metal film 45.

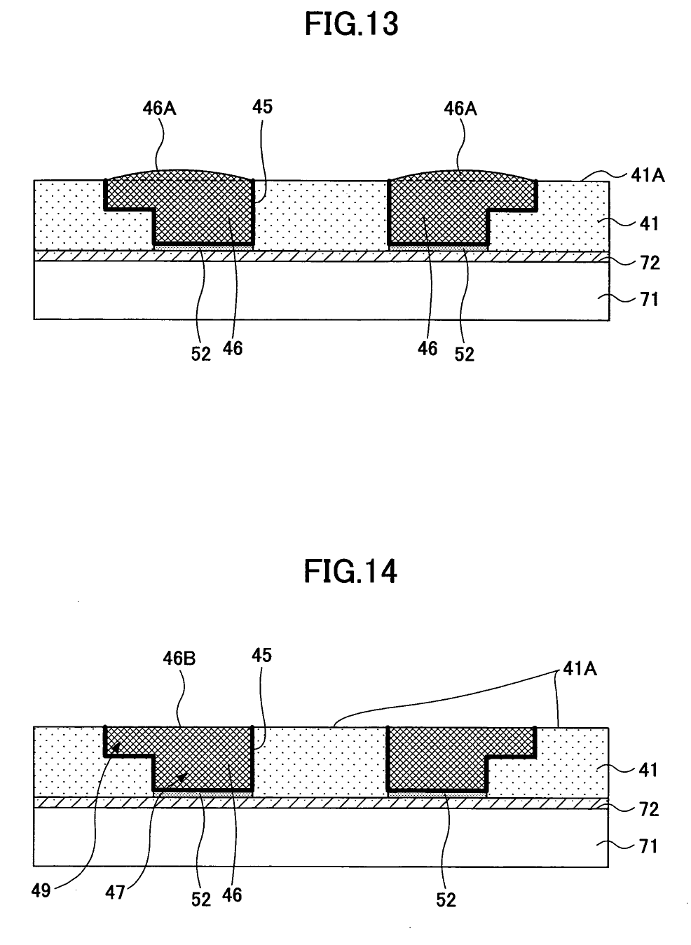

Next, as shown in FIG. 12, the metal film 45 formed on the surface 41A of the base material 41 is removed through polishing so that the metal film 45 only remains at the inner walls of openings 74 (metal film formation step). Next, as shown in FIG. 13, metal film 45 is used as a current supply layer to induce deposition growth of the Cu plating film 46 at the openings 74 through electroplating (plating film formation step). In FIG. 13, Cu plating film portions 46A protrude from the surface 41A of the base material 41.

Next, as shown in FIG. 14, Cu plating film portions 46A protruding from the surface 41A of the base material 41 are polished so that the Cu plating film surface 46B of Cu plating film 46 are coplanar with the surface 41A of the base material 41 (plating polishing step). Thus, wiring portions 48 (connection pads 49 and wirings 51) formed at trench portions 76 and via portions 47 formed at through holes 75 may be positioned coplanar to surface 41A of base material 41.

By positioning wiring portions 48 coplanar to surface 41A of base material 41, connections pads 49 and wirings 51 may not protrude from the surface 41A of base material 41; consequently, after connecting the semiconductor element 63 to base material 41, gap 67 between the semiconductor element main body 64 and substrate 40 is evenly formed with sufficient width. In the plating film formation step, if the extent of protrusion of the Cu plating film portions 46A is negligible, the plating film polishing step may be omitted.

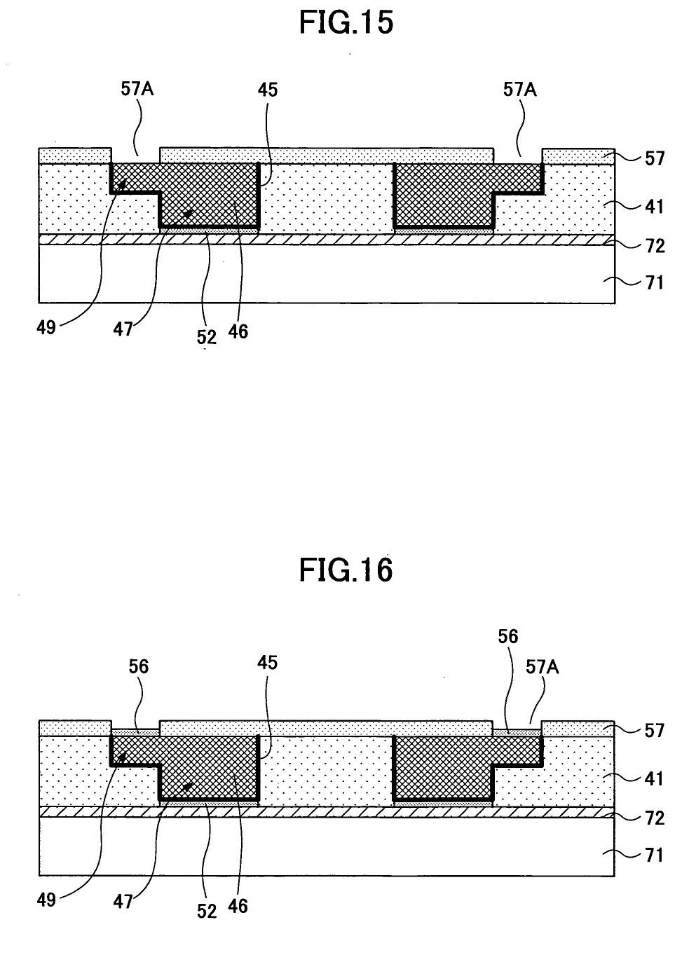

Next, referring to FIG. 15, solder resist 57 having openings 57A for covering wirings 51 and via portions 47 and exposing connection pads 49 (insulating layer formation step) is formed. Then, as shown in FIG. 16, diffusion barrier film 56 made of a Ni/Au laminated film, for example, is prepared by electroplating on connection pads 49 which are exposed by openings 57A. It should be noted that solder film (formed through solder plating) suitable for realizing connection with the semiconductor element 63 maybe used in place of the diffusion barrier film 56.

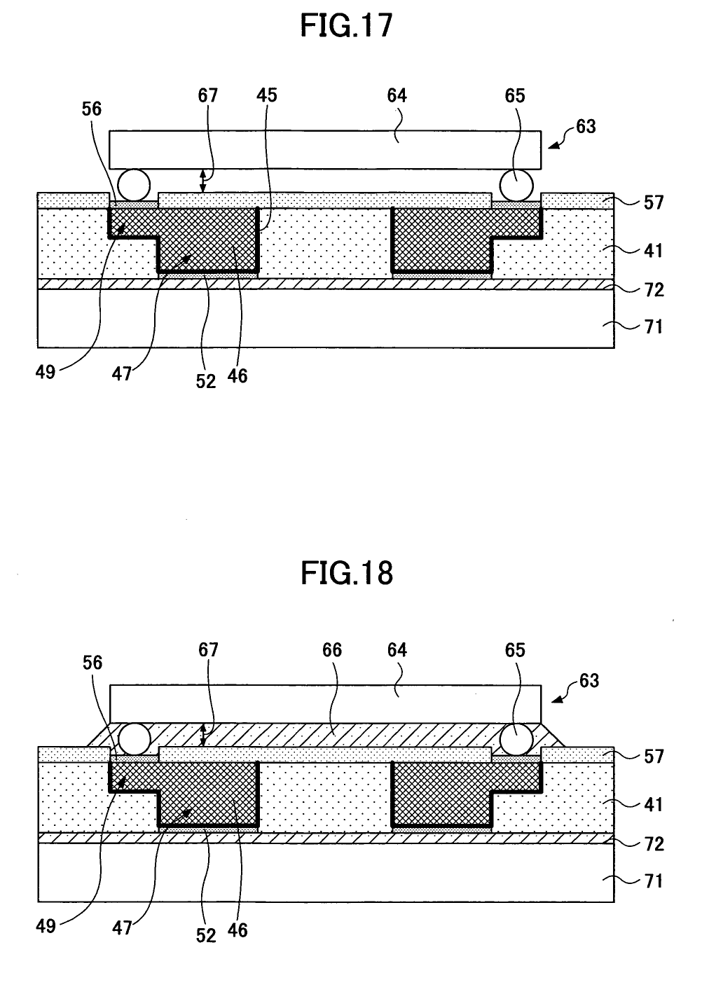

Next, as shown in FIG. 17, with the base material 41 being supported by the support member 71, solder bumps 65 of the semiconductor element 63 are flip-chip connected to the connection pads 49 via the diffusion barrier film 56 (semiconductor element connection step).

By connecting the semiconductor element 63 to the connection pads 49 in a state where the base material 41 is supported by the support member 71, base material 41 may be prevented from deforming even when the thickness M1 of the base material 41 is relatively thin, and solder bumps 65 of the semiconductor element 63 may be properly connected to the connection pads 49.

Next, as shown in FIG. 18, underfill resin 66 is arranged within gap 67 between the semiconductor element main body 64 and solder resist 57 (underfill material providing step). Thus, underfill resin 66 may form evenly with a sufficient thickness within gap 67 so that sufficient connection reliability may be realized between the substrate 40 and the semiconductor element 63.

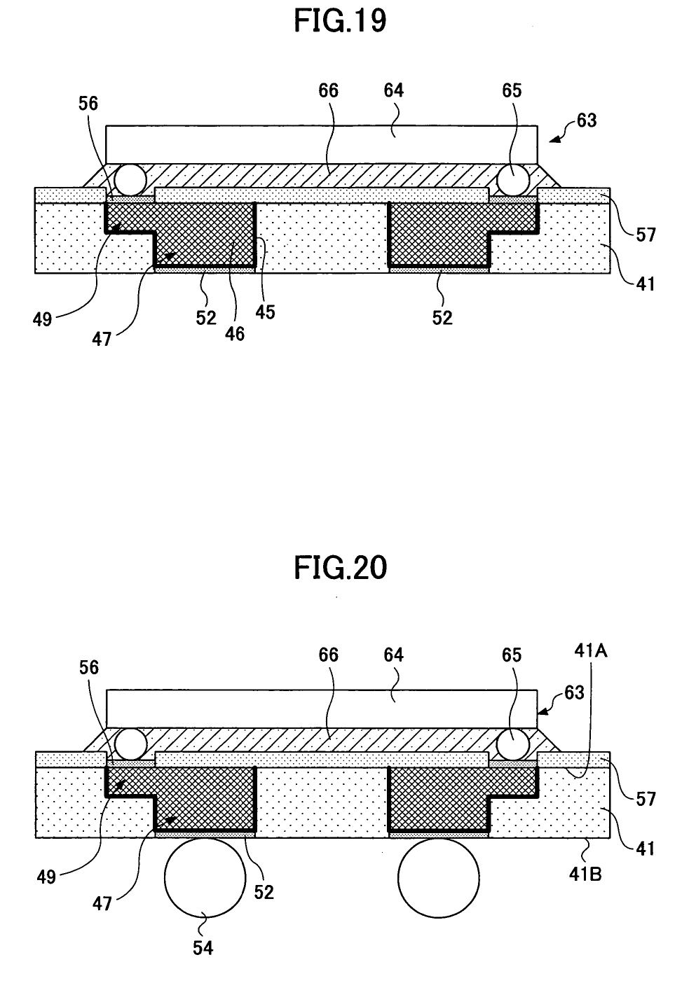

Next, as shown in FIG. 19, there is a removal process for removing the support member 71 and metal layer 72 (support member removal step). The removal process for removing support member 71 and metal layer 72 is as follows. If support member 71 is a resin board, then support member 71 may be peeled off before metal layer 72 is removed through wet etching. If the support member 71 is made of polyimide (resin) and metal layer 72 is prepared on the surface of support member 71 through electroless plating, then support member 71 may be easily peeled off from metal layer 72. If copper is used in preparing metal layer 72, then only the metal layer 72 can be removed effectively because diffusion barrier film 52 is not easily dissolved by the etching solution used for etching copper. If the support member 71 is a metal sheet, then support member 71 may be removed through wet etching. Alternatively, the metal sheet corresponding to the support member 71 may be removed through polishing before metal layer 72 is removed through wet etching.

Next, as shown in FIG. 20, the solder balls 54 are connected to the via portions 47 via the diffusion barrier film 52. Thus, the semiconductor device 60 with the base material 40 and the semiconductor element 63 connected thereto may be fabricated. It should be noted that in an alternative embodiment, the solder balls 54 do not have to be arranged and the diffusion barrier film 52 may be used as an external connection terminal to realize the semiconductor device 60.

As implied from the aforementioned description of the present embodiment, by positioning the wiring portions 48 and the via portions 47 coplanar to the surface 41A of the base material 41, gap 67 between the semiconductor element main body 64 and the substrate 40 forms evenly and with a sufficient width so that underfill resin 66 is distributed in gap 67 with sufficient thickness. Thus, the connection between the substrate 40 and the semiconductor element 63 may be strengthened, preventing damage to substrate 40 and/or the semiconductor element 63. Also, according to the present embodiment, even when the thickness M1 of the base material 41 is relatively thin, the substrate 40 may be properly processed, and the solder bumps 65 of semiconductor element 63 may be adequately connected to the connection pads 49.

According to a modified example, as shown in FIG. 21, the Cu plating film 46 maybe formed on the structure shown in FIG. 11, and the structure shown in FIG. 14 may be formed thereafter through polishing. Then, the process steps of FIGS. 15 through 20 may be performed to fabricate the semiconductor device 60. (Second Embodiment In the following, referring to FIG. 22, a semiconductor device 100 according to a second embodiment of the present invention is described. FIG. 22 is a cross-sectional view of the semiconductor device 100 according to the second embodiment. Semiconductor device 100 is comprised of a substrate 80 and the semiconductor element 63. In the semiconductor device 100 according to the present embodiment, the semiconductor element 63 is flip-chip connected to the substrate 80, and gap 110 is formed at the junction between the semiconductor element main body 64 and substrate 80, wherein underfill resin 98 is arranged.

Semiconductor element 63 is comprised of semiconductor element main body 64 and solder bumps 65 corresponding to first external connection terminals. Solder balls 65 are connected to ends of via portions 87 at a surface 81A side of the base material 81 via a diffusion barrier film 95.

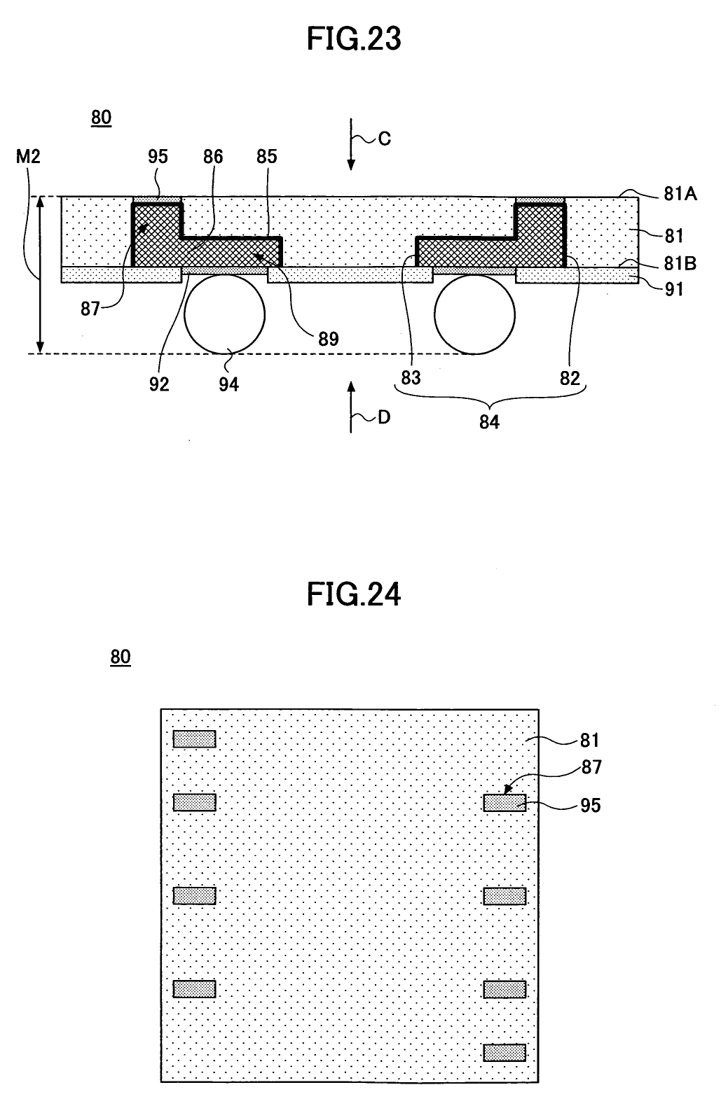

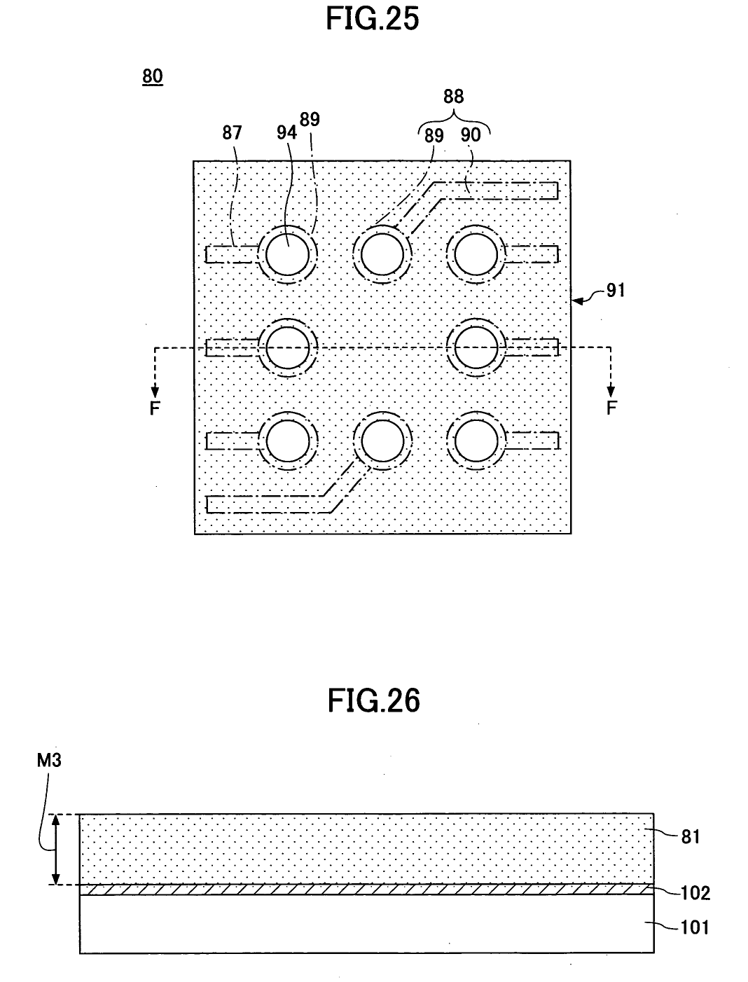

FIGS. 23 through 25 illustrate substrate 80 according to the present embodiment. FIG. 23 is a cross-sectional view of the substrate 80 cut across line F-F of FIG. 25; FIG. 24 is a plan view of the substrate 80 viewed from side C of FIG. 23; and FIG. 25 is a plan view of the substrate 80 viewed from side D of FIG. 23.

Substrate 80 is comprised of a base material 81, via portions 87, wiring portions 88, diffusion barrier films 92, 95, solder balls 94, and solder resist 91. Openings 84 are formed at the base material 81 for accommodating via portions 87 and wiring portions 88. Openings 84 include through holes 82 for accommodating via portions 87, and trench portions 83 for accommodating the wiring portions 88. Base material 81 may be a resin base material, for example. It should be noted that in the following description of the present embodiment, it is assumed that a resin base material is used as the base material 81.

Via portions 87 provided at through holes 82 penetrate base material 81. Via portions 87 form integral structures with their corresponding wiring portions 88 provided at trench portions 83. Solder bumps 65 of semiconductor element 63 are connected to the end of via portions 87 at which the wiring portions 88 are not formed.

By positioning solder bumps 65 of the semiconductor element 63 so that they are connected to the ends on the side of the via portions 87 at which the wiring portions 88 are not formed, the gap between the semiconductor element main body 64 and substrate 80 form evenly and with a sufficient width. Accordingly, the underfill resin 98 may be evenly distributed within the gap 110 with a sufficient thickness, to thereby improve the connection reliability between the semiconductor element 63 and the substrate 80.

Via portions 87 and wiring portions 88 are formed using metal film 85 and a Cu plating film 86. Metal film 85 corresponds to a current supply layer used for forming the Cu plating film 86 through electroplating. For example, Ni film or a Cu film prepared by electroless plating may be used as metal film 85.

Wiring portions 88, which forms integral structures with via portions 87, are arranged on the surface 81B side of base material 81, and include connection pads 89 and the wirings 90. Connection pads 89 are configured to realize connection with the solder balls 94 corresponding to second external connection terminals. Wirings 90 are configured to realize electrical connection between the connection pads 89 and via portions 87. Wirings 88 and via portions 87 are positioned coplanar to the surface 81B of the base material 81.

As described above, according to the present embodiment, wirings 88 are positioned coplanar to the surface 81B of the base material 81, thereby preventing connection pads 89 and wirings 90 from protruding from the surface 81B of base material 81. Accordingly, this reduces the thickness M2 of the substrate 80 in comparison to that of the prior art substrate 10, facilitating the miniaturization of substrate 80.

Solder resist 91, which corresponds to an insulating film formed on the base material 81, is positioned to cover both via portions 87 and the wirings 90, and expose connection pads 89. Solder resist 91 is configured to prevent the occurrence of solder shorts upon connecting the solder balls 94 to the connection pads 89 and protect via portions 87 and wirings 90. Diffusion barrier film 92 is arranged on the connection pads 89 that are exposed by solder resist 91. Diffusion barrier film 92 is configured to improve the wettability of solder and prevent diffusion of Cu contained in the connection pads 89 into solder balls 94. For example, a Ni/Au layer may be employed for diffusion barrier film 92. Solder balls 94 corresponding to second external connection terminals are connected to connection pads 89 via the diffusion barrier film 92. Solder balls 94 are configured to realize electrical connection between substrate 80 and another substrate such as a motherboard.

Via portions 87, which penetrate base material 81, are integrally formed with wiring portions 88. Diffusion film 95 is positioned at the ends of the via portions 87 on the surface 81A side of the base material 81, and is coplanar with the surface 81A of the bas material 81. Via portions 87 with diffusion barrier film 95 provided thereon is electrically connected with solder bumps 65 of semiconductor element 63. Diffusion barrier film 95 is configured to improve the wettability of solder and prevent diffusion of Cu contained in via portions 87 into solder bumps 65. Ni/Au layer, for example, may be used as diffusion barrier film 95.

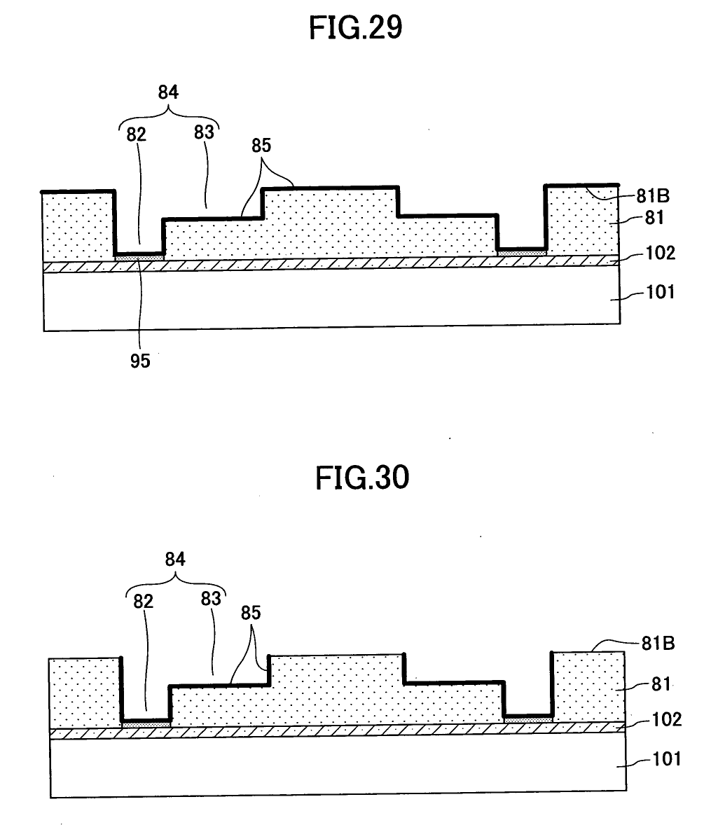

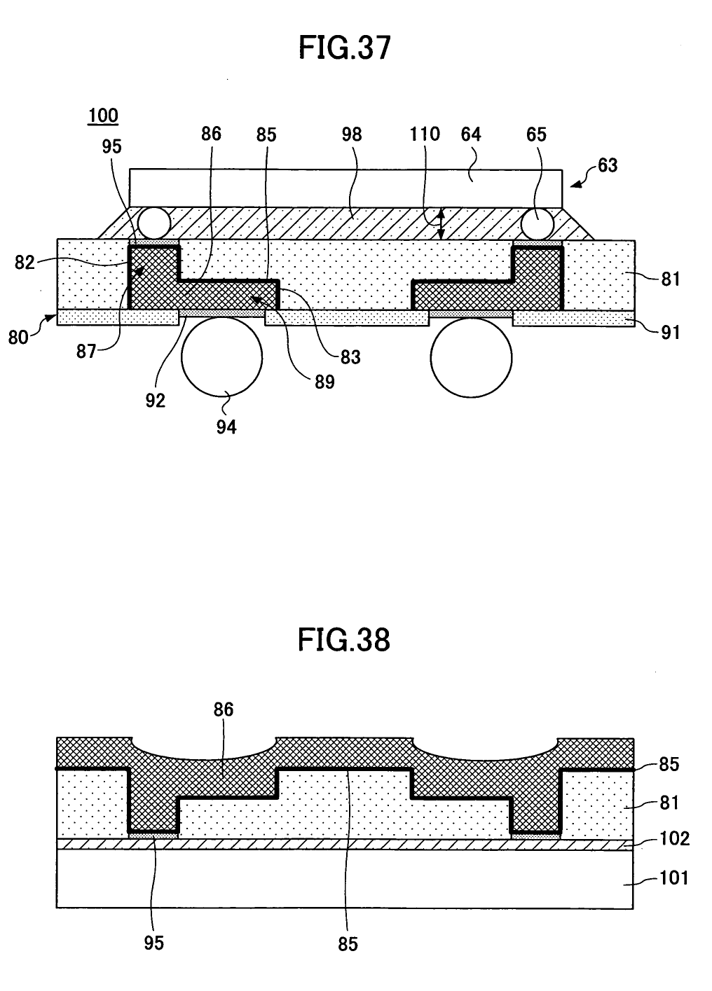

FIGS. 26 through 36 describe a method of fabricating the substrate 80 according to the second embodiment. FIGS. 26 through 36 provide diagrams illustrating process steps for fabricating the substrate 80 of the present embodiment. FIG. 37 is a cross-sectional view of the semiconductor device 100 that is formed by connecting the semiconductor element 63 to the substrate 80 shown in FIG. 36. FIG. 38 is a diagram illustrating a process step of forming the Cu plating film 86 on the structure shown in FIG. 29 through deposition growth.

First, as shown in FIG. 26, a metal layer 102 is arranged on a support member 101, and base material 81 is arranged on the support member 101 through the metal layer 102 (base material mounting step). Support member 101 is provided in order to prevent deformation such as bending and warping of the base material 81 that may occur when the thickness M3 of the base material 81 is relatively thin. For example, a resin sheet made of resin material such epoxy or polyimide, or a metal sheet made of metal such as aluminum or copper may be used as the support member 101. When using a metal sheet as support member 101, metal layer 102 does not have to be provided, and the step of forming the metal layer 102 may be omitted.

By mounting the base material 81 on the support member 101, substrate 80 forms properly even when the thickness M3 of the base material 81 is relatively thin. Metal layer 102 corresponds to a current supply layer that is used upon forming the diffusion barrier film 95 through electroplating. Metal layer 102 may be formed through a electroless plating process or a sputtering process, for example. Also, materials such as Cu, Ni, or Al may be used in preparing metal layer 102. According to one embodiment, base material 81 may be prepared by applying resin on the support member 101 having the metal layer 102 provided thereon.

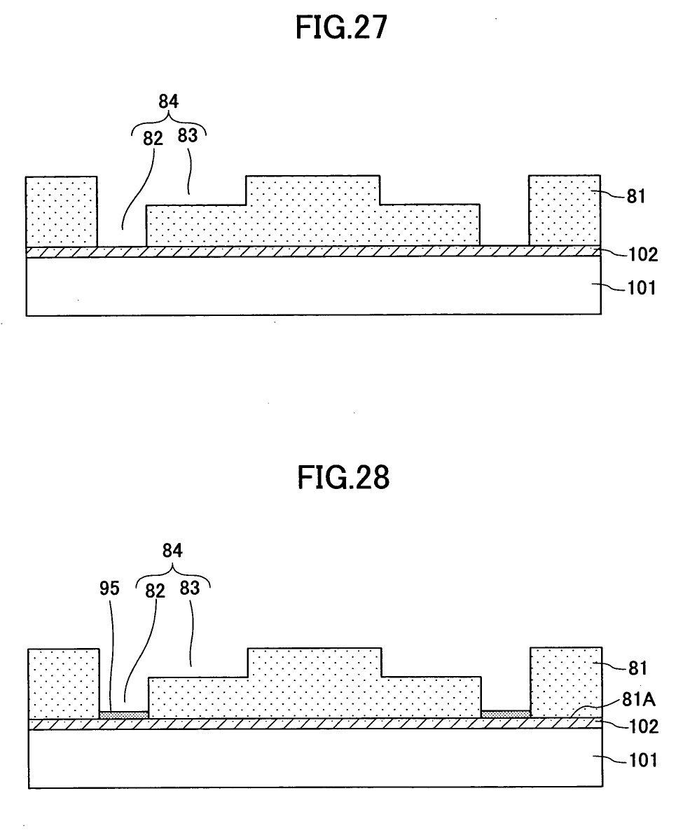

Next, as shown in FIG. 27, openings 84 are formed in the base material 81 (opening formation step). Openings 84 are each comprised of trench portion 83 and through hole 82 forming an integral structure with the trench portion 83. Through holes 82 are arranged to expose the metal layer 102. Openings 84 may be formed by a drilling process, for example, using a drill, a laser process, or an imprint process using a microscopic tool. When using an imprint process, resin (corresponding to the base material 81 of FIG. 27) maybe applied to support member 101 having metal layer 102 formed thereon, or a resin film (corresponding to the base material 81 of FIG. 27) maybe laminated on the support member 101. The resin (or resin film) is then semi-hardened. Subsequently, a microscopic tool, designed with convex portions for forming openings 84, is pressed against the semi-hardened resin (or resin film) transferring the convex shape of portions of the microscopic tool to the resin (or resin film). Then, the resin (or resin film) is hardened through a thermal process to form openings 84 on the base material 81.

Next, as shown in FIG. 28, metal layer 102 is used as a current supply layer to form diffusion barrier film 95 at the bottom portions of through holes 82 through electroplating. Alternatively, a solder film (formed through solder plating) suitably for realizing connection with the solder balls 65 may be used in place of the diffusion barrier film 95.

By arranging diffusion barrier film 95 to which solder bumps 65 of semiconductor element 63 are connected in a coplanar fashion to surface 81A of base material 81, gap 110 between the semiconductor element main body 64 and substrate 80 forms evenly and sufficiently wide when the semiconductor element 63 is connected to substrate 80.

Next, as shown in FIG. 29, the metal film 85 is formed on the structure shown in FIG. 28. The metal film 85 corresponds to a current supply layer for inducing deposition growth of Cu plating film 86 at openings 84. Metal film 85 may be prepared using electroless plating or sputtering, for example. Alternatively, copper or nickel may be used in preparing metal film 85.

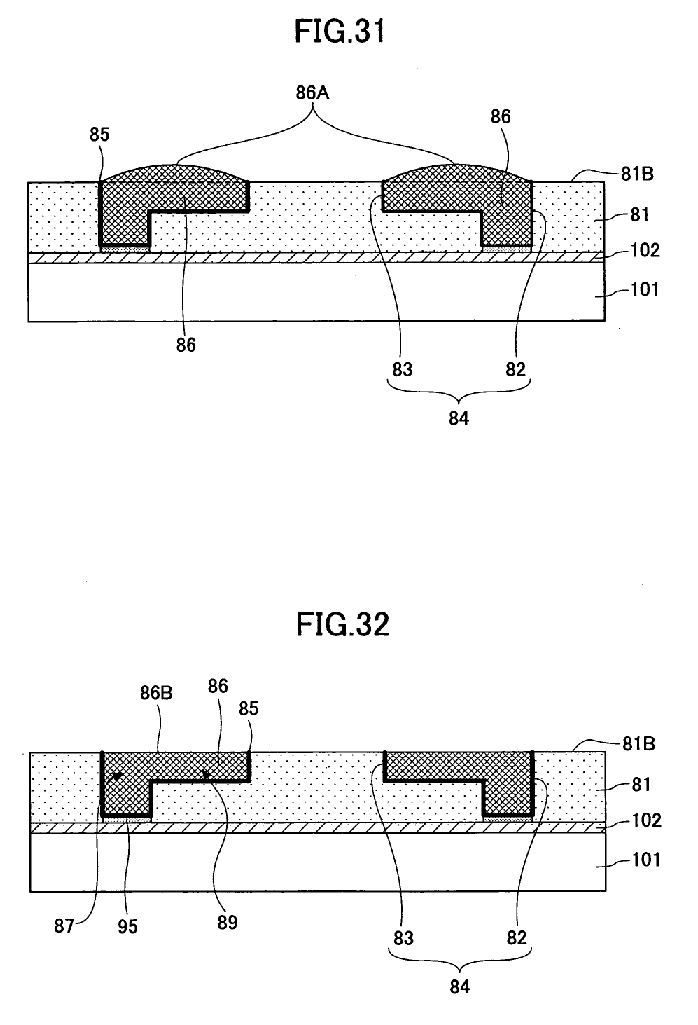

Next, as shown in FIG. 30, metal film 85 formed on the surface 81B of the base material 81 is removed through polishing so that the metal film 85 only remains at the inner walls of the openings 84 (metal film formation step). Next, as shown in FIG. 31, metal film 85 is used as a current supply layer to induce deposition growth of the Cu plating film 86 at the openings 84 through electroplating (plating film formation step). In FIG. 31, Cu plating film portions 86A protrude from surface 81B of base material 81.

Next, as shown in FIG. 32, Cu plating film portions 86A protruding from surface 81B of base material 81 are polished so that Cu plating film surface 86B of Cu plating film 86 are coplanar with the surface 81B of the base material 81 (plating polishing step). Thus, wiring portions 88 (not shown) formed at trench portions 83 and via portions 87 formed at through holes 82 are positioned coplanar to surface 81B of base material 81.

By positioning wiring portions 88 coplanar to the surface 81B of base material 81, the thickness M2 of substrate 80 is reduced in comparison to that of the prior art substrate 10, facilitating miniaturization of the substrate 80. In the plating film formation step, if the extent of protrusion of the Cu plating film portions 86A is negligible, the plating film polishing step may be omitted.

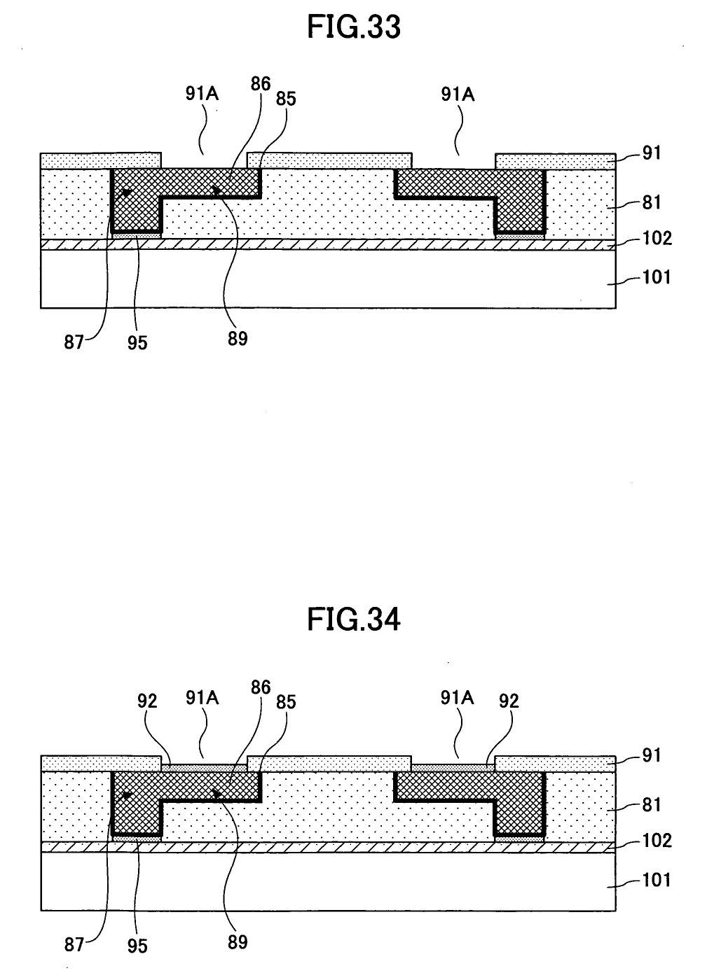

Next, in FIG. 33, solder resist 91 having openings 91A, for covering wirings 90 and via portions 87 and exposing connection pads 89 is formed on the structure shown in FIG. 32 (insulating layer formation step). Then, as shown in FIG. 34, diffusion barrier film 92 is formed on the connection pads 89 by electroplating. Alternatively, a solder film (formed through solder plating) suitable for realizing connection with the solder balls 94 may be used in place of the diffusion barrier film 92.

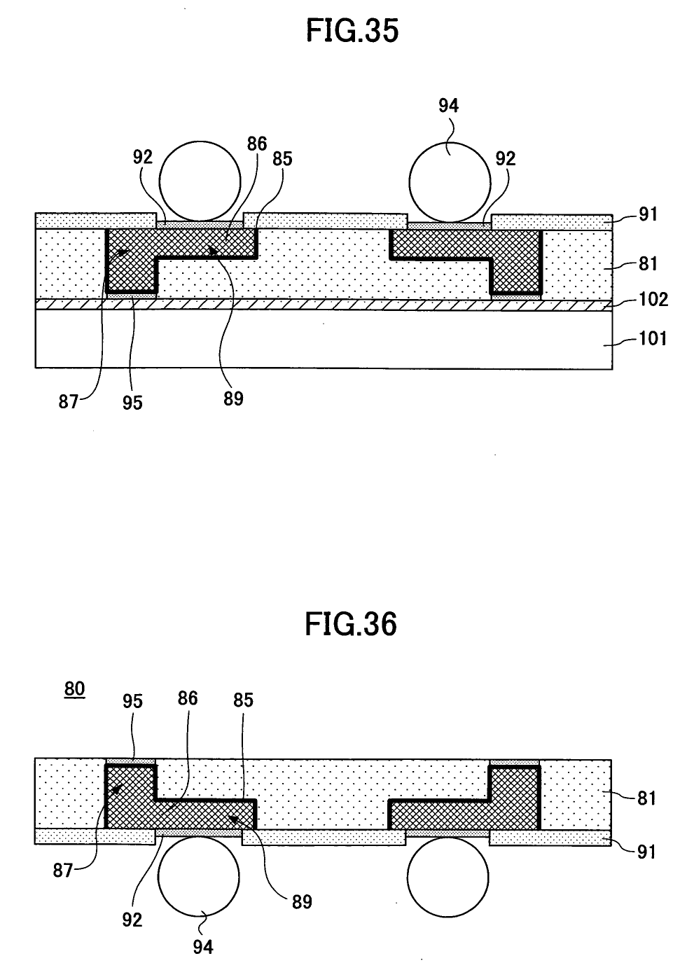

Next, in FIG. 35, solder balls 94 are arranged on the diffusion barrier film 92. Substrate 80 is thus formed. It should be noted that in an alternative embodiment, the solder balls 94 do not have to be arranged, and the diffusion barrier film may be used as en external connection terminal. Then, FIG. 36 illustrates the process for removing the support member 101 and the metal layer 102 (support member removal step). The removal process for removing the support member 101 and the metal layer 102 is as follows. If the support member 101 is a resin sheet, then support member 101 is peeled off, and then metal layer 102 is removed through wet etching. If support member 101 is made of polyimide (resin) and the metal layer 102 is formed on the surface of the support member 101 through electroless plating, then support member 101 may be easily peeled off from the metal layer 102. If copper is used in preparing metal layer 102, only metal layer 102 is removed since the diffusion barrier film 95 is not easily dissolved by the etching solution used for etching copper. If support member 101 is a metal sheet, the support member 101 may be removed through wet etching. Alternatively, the metal sheet corresponding to the support member 101 may be removed through polishing before the metal layer 102 is removed through wet etching.

Next, as shown in FIG. 37, solder bumps 65 of semiconductor element 63 are flip-chip connected to connection pads 87 via diffusion barrier film 95, and underfill resin 98 is distributed within the gap between the semiconductor element main body 64 and substrate 80 so that the semiconductor device 100 may be fabricated.

By forming the substrate 80 according to the fabricating method described above, the underfill resin 98 may be distributed evenly and with sufficient thickness in gap 110 (between the semiconductor element main body 64 and the substrate 80), maintaining adequate connection reliability between the substrate 80 and the semiconductor element 63. Also, substrate 80 may form properly even when the thickness M3 of the base material 81 is relatively thin. Furthermore, by positioning wiring portions 88 coplanar to the surface 81B of base material 81 and reducing the thickness M2 of substrate 80, miniaturization of the substrate 80 may be effectively achieved.

In the plating film formation step, if the extent of protrusion of Cu plating film portions 86A (amount of protrusion with respect to the surface 81B of the base material 81) is negligible, the plating film polishing step may be omitted. Also, according to a modified example, as shown in FIG. 38, the Cu plating film 86 maybe formed on the structure shown in FIG. 29, and a polishing process may be performed on the structure of FIG. 38 thereafter to realize the structure shown in FIG. 32. Then, the process steps shown in FIGS. 33 through 36 may be performed to fabricate the substrate 80.

Although preferred embodiments of the present invention have been described above, the present invention is not limited to these specific embodiments, and variations and modifications may be made without departing from the scope of the present invention. For example, base materials 41 and 81 used in the substrates 40 and 80 of the first and second embodiments of the present invention are not limited to resin base materials.

The present application is based on and claims the benefit of the earlier filing date of Japanese Patent Application No. 2004-245468 filed on Aug. 25, 2004, the entire contents of which are hereby incorporated by reference.

What is claimed is:

1. A substrate to which a semiconductor element having a first external connection terminal is connected, the substrate comprising:
a base material;
a wiring portion that is provided at a first surface side of the base material and is configured to realize connection with the first external connection terminal, the wiring portion being arranged to be coplanar with the first surface of the base material; and
a via portion that is integrally formed with the wiring portion and is arranged to penetrate through the base material.

2. The substrate as claimed in claim 1, further comprising:
an insulating layer that is arranged on the first surface side of the base material; wherein
the wiring portion includes a connection pad to which the first external connection terminal is connected and wiring for realizing connection between the connection pad and the via portion; and
the insulating layer is arranged to cover the via portion and the wiring, and expose the connection pad.

3. The substrate as claimed in claim 1r further comprising:
a second external connection terminal that is configured to realize connection with another substrate, the second external connection terminal being connected to the via portion at a second surface side of the base material on the opposite side of the first surface.

4. A semiconductor device, comprising:
a semiconductor element having a first external connection terminal;
a substrate to which the semiconductor element is connected which substrate includes
a base material;
a wiring portion that is provided at a first surface side of the base material and is configured to realize connection with the first external connection terminal, the wiring portion being arranged to be coplanar with the first surface of the base material; and
a via portion that is integrally formed with the wiring portion and is arranged to penetrate through the base material; and
an underfill material that is provided at a gap formed between the semiconductor element and the substrate.

5. A substrate to which a semiconductor element having a first external connection terminal is connected, the substrate comprising:
a base material;
a second external connection terminal that is configured to realize connection with another substrate;
a wiring portion that is provided at a first surface side of the base material and is configured to realize connection with the second external connection terminal, the wiring portion being arranged to be coplanar with the first surface of the base material;
a via portion that is integrally formed with the wiring portion and is arranged to penetrate through the base material;
wherein the first external connection terminal is connected to the via portion at a second surface side of the base material on the opposite side of the first surface.

6. The substrate as claimed in claim 5, further comprising:
an insulating layer that is provided on the first surface side of the base material; wherein
the wiring portion includes a connection pad to which the second external connection terminal is connected, and a wiring for realizing connection between the connection pad and the via portion; and
the insulating layer is arranged to cover the via portion and the wiring, and expose the connection pad.

7. A semiconductor device, comprising:
a semiconductor element having a first external connection terminal;
a substrate to which the semiconductor element is connected which substrate includes
a base material;
a second external connection terminal that is configured to realize connection with another substrate;
a wiring portion that is provided at a first surface side of the base material and is configured to realize connection with the second external connection terminal, the wiring portion being arranged to be coplanar with the first surface of the base material;
a via portion that is integrally formed with the wiring portion and is arranged to penetrate through the base material;
wherein the first external connection terminal is connected to the via portion at a second surface side of the base material on the opposite side of the first surface; and
an underfill material that is provided at a gap formed between the semiconductor element and the substrate.

8. A method of fabricating a substrate to which a semiconductor element having a first external connection terminal is connected, which substrate includes a base material, a wiring portion to which the first external connection terminal is connected, and a second external connection terminal for realizing connection with another substrate, the method comprising:
an opening formation step for forming at the base material an opening that includes a trench portion and a through hole;
a metal film formation step for forming a metal film at an inner wall of the opening; and
a plating film formation step for forming a plating film at the opening through electroplating using the metal film as a current supply layer and inducing deposition growth of the plating film, forming at the through hole a via portion to which the second external connection terminal is connected, and forming at the trench portion a wiring portion to which the first external connection terminal is connected.

9. The method as claimed in claim 8, further comprising:
a plating film polishing step that is performed when the plating film formed in the plating film formation step protrudes from a surface of the base material, the plating film polishing step involving polishing the protruding plating film and arranging the plating film to be coplanar with the surface of the base material.

10. The method as claimed in claim 8, further comprising:
an insulating layer formation step for forming an insulating layer on the base material; wherein
the wiring portion includes a connection pad to which the first external connection terminal is connected and wiring for realizing connection between the connection pad and the via portion; and
the insulating layer is arranged to cover the via portion and the wiring, and expose the connection pad.

11. A method of fabricating a semiconductor device that includes a substrate having a base material and a wiring portion, a semiconductor element having a first external connection terminal that is connected to the wiring portion, and an underfill material that is provided at a gap formed between the substrate and the semiconductor element connected to said substrate, the method comprising:
a base material providing step for providing the base material on a support member that is configured to support the base material;
a substrate fabricating step for fabricating the substrate which substrate fabricating step includes
an opening formation step for forming at the base material an opening that includes a trench portion and a through hole;
a metal film formation step for forming a metal film at an inner wall of the opening; and
a plating film formation step for forming a plating film at the opening through electroplating using the metal film as a current supply layer and inducing deposition growth of the plating film, forming at the through hole a via portion to which the second external connection terminal is connected, and forming at the trench portion a wiring portion to which the first external connection terminal is connected;
a semiconductor element connection step for connecting the first external connection terminal to the wiring portion;
an underfill material providing step for providing the underfill material at the gap formed between the semiconductor element and the substrate; and
a support member removal step for removing the support member.

12. A method of fabricating a substrate to which a semiconductor element having a first external connection terminal is connected, which substrate includes a base material, a second external connection terminal for realizing connection with another substrate, and a wiring portion to which the second external connection terminal is connected, the method comprising:
an opening formation step for forming at the base material an opening that includes a trench portion and a through hole;
a metal film formation step for forming a metal film at an inner wall of the opening; and
a plating film formation step for forming a plating film at the opening through electroplating using the metal film as a current supply layer and inducing deposition growth of the plating film, forming at the through hole a via portion to which the first external connection terminal is connected, and forming at the trench portion a wiring portion to which the second external connection terminal is connected.

13. The method as claimed in claim 12 further comprising:
a plating film polishing step that is performed when the plating film formed in the plating film formation step protrudes from a surface of the base material, the plating film polishing step involving polishing the protruding plating film and arranging the plating film to be coplanar with the surface of the base material.

14. The method as claimed in claim 12, further comprising:
an insulating layer formation step for forming an insulating layer on the base material; wherein
the wiring portion includes a connection pad to which the second external connection terminal is connected and wiring for realizing connection between the connection pad and the via portion; and
the insulating layer is arranged to cover the via portion and the wiring, and expose the connection pad.
